(19) United States
(12) Patent Application Publication
(10) Pub. No.: US 2023/0104002 A1
(43) Pub. Date: Apr. 6, 2023

(54) POWER CONVERSION DEVICE

(71) Applicant: FUJI ELECTRIC CO., LTD., Kawasaki-shi (JP)

(72) Inventors: Toshiaki AZUMA, Amagasaki-shi (JP); Shun FUKUCHI, Suzuka-shi (JP)

(21) Appl. No.: 17/892,453

(22) Filed: Aug. 22, 2022

(30) Foreign Application Priority Data
Oct. 1, 2021 (JP) 2021-162828

(51) Int. Cl. H05K 7/20; H02M 3/00; H02M 7/00

(52) U.S. Cl. CPC H05K 7/20927; H02M 3/003; H02M 7/003; H05K 7/20436; H05K 7/20263

(57) ABSTRACT

This power conversion device includes an inverter, a DC-DC converter, and a flat plate-shaped base where the inverter and the DC-DC converter are disposed on the front side and the back side. The base includes a cooling flow path having a front side flow path disposed on the front side and a back side flow path connected to the front side flow path and disposed on the back side.

### CROSS-REFERENCE TO RELATED APPLICATION

The disclosures of Japanese Patent Application number JP2021-162828, power conversion device, filed on Oct. 1, 2021 and invented by Toshiaki AZUMA and Shun FUKUCHI upon which this patent application is based, are hereby incorporated by reference.

### BACKGROUND OF THE INVENTION

### Field of the Invention

This invention relates to a power conversion device, and more particularly to a power conversion device including a cooling flow path.

### Background Art

A power conversion device including a cooling flow path is known in the related art. Such a power conversion device is disclosed in, for example, Japanese Unexamined Patent Publication No. 2009-027901.

Japanese Unexamined Patent Publication No. 2009-027901 discloses a power conversion device including an inverter, a DC-DC converter, and a cooling flow path through which a refrigerant cooling the inverter and the DC-DC converter flows. In this power conversion device, the inverter and the DC-DC converter are disposed with the cooling flow path interposed therebetween, and the inverter and the DC-DC converter are cooled by the refrigerant flowing through the interposed cooling flow path.

In Japanese Unexamined Patent Publication No. 2009-027901, the inverter and the DC-DC converter (DC-DC converter) are disposed with the cooling flow path interposed therebetween, and the inverter and the DC-DC converter are cooled by the refrigerant flowing through the interposed cooling flow path. Accordingly, the inverter is cooled by some of the refrigerant that flows through the cooling flow path on the inverter side, and the DC-DC converter is cooled by some of the refrigerant that flows on the DC-DC converter side. Accordingly, in a case where there is a temperature difference between the inverter and the DC-DC converter, a temperature difference occurs between the refrigerants flowing at the same position in the cooling flow path. This leads to a problem of causing unintended convection in the refrigerant attributable to the temperature difference and making it difficult to perform cooling efficiently.

### SUMMARY OF THE INVENTION

This invention has been made to solve the above problem, and one object of this invention is to provide a power conversion device capable of efficiently cooling an inverter and a DC-DC converter.

In order to achieve the above object, a power conversion device according to a first aspect of this invention includes: an inverter converting DC power input from a DC power supply into AC power and supplying the power to a load; a DC-DC converter converting a voltage of the DC power into a different voltage; and a flat plate-shaped base where the inverter and the DC-DC converter are disposed on a front side and a back side, in which the base includes a cooling flow path flowing cooling liquid and having a front side flow path disposed on the front side and a back side flow path connected to the front side flow path and disposed on the back side.

In the power conversion device according to the first aspect of this invention, as described above, the inverter and the DC-DC converter are disposed on the front side and the back side of the flat plate-shaped base, and the base is provided with the cooling flow path having the front side flow path disposed on the front side and the back side flow path connected to the front side flow path and disposed on the back side. As a result, the cooling liquid is capable of sequentially flowing through the front side flow path and the back side flow path, and thus the inverter and the DC-DC converter disposed on the front side and the back side of the base can be sequentially cooled. As a result, it is possible to suppress the occurrence of a temperature difference between the cooling liquids flowing at the same position, and thus it is possible to suppress the generation of unintended convection of the cooling liquid attributable to a temperature difference. As a result, the inverter and the DC-DC converter can be efficiently cooled by the cooling liquid flowing through the cooling flow path. In addition, as compared with the case of a configuration in which the inverter and the DC-DC converter are disposed in separate bases and cooled by the cooling flow paths respectively provided in the bases, the configuration of the power conversion device including the inverter and the DC-DC converter can be made compact.

In the power conversion device according to the first aspect, preferably, the cooling flow path further has a connection flow path connecting the front side flow path and the back side flow path in the base. With such a configuration, the cooling flow path can be formed such that the cooling liquid sequentially flows through the front side flow path and the back side flow path in the base, and thus the configuration of the base can be simplified unlike in a case where the front side flow path and the back side flow path are connected outside the base.

In the power conversion device according to the first aspect, preferably, the cooling flow path is formed such that the front side flow path and the back side flow path are alternately connected and the cooling liquid alternately passes through a front side surface and a back side surface of the base. With such a configuration, a cooling liquid is capable of alternately and sequentially flowing through the front side flow path and the back side flow path, and thus the inverter and the DC-DC converter disposed on the front side and the back side of the base can be alternately and sequentially cooled.

In the power conversion device configured such that the cooling flow path has the connection flow path, preferably, the connection flow path has a chamfered corner. With such a configuration, an increase in pressure loss in the corner of the connection flow path can be suppressed as compared with a case where the connection flow path has no chamfered corner.

In the power conversion device configured such that the cooling flow path has the connection flow path, preferably, the connection flow path includes a partition plate adjusting a flow of the cooling liquid flowing into at least one of the front side flow path and the back side flow path.

In the power conversion device configured such that the cooling flow path has the connection flow path, preferably, the cooling flow path includes a groove inclined to the connection flow path.

In the power conversion device according to the first aspect, preferably, the inverter is disposed on one of the front side and the back side of the base and is cooled by the cooling liquid flowing through one of the front side flow path and the back side flow path, and the DC-DC converter is disposed on the other of the front side and the back side of the base and is cooled by the cooling liquid flowing through the other of the front side flow path and the back side flow path. With such a configuration, the components and elements included in the inverter can be disposed on one surface of the base, and the components and elements included in the DC-DC converter can be disposed on the other surface of the base. Accordingly, it is possible to suppress an increase in the wiring connecting the front side and the back side of the base. As a result, it is possible to suppress the wiring structure of the power conversion device becoming complex.

In the power conversion device according to the first aspect, preferably, the base includes a metallic cooling main body where the cooling flow path is formed and a metallic lid forming the cooling flow path together with the cooling main body, and at least one of the inverter and the DC-DC converter is attached to the lid disposed on the front side and the back side of the base. With such a configuration, the lid to which the inverter or the DC-DC converter is attached can be brought into direct contact with the cooling liquid flowing through the cooling flow path, and thus heat can be efficiently removed from the inverter and the DC-DC converter via the lid.

In this case, preferably, the lid is provided with a protuberance protruding into the cooling flow path. With such a configuration, the area of contact of the lid with the cooling liquid can be increased by the protuberance, and thus heat from the inverter and the DC-DC converter can be more efficiently transferred to the cooling liquid via the lid.

In the power conversion device configured such that the lid is provided with the protuberance, preferably, the protuberance of the lid is formed in a fin shape, a cylindrical shape, or a prismatic shape. With such a configuration, heat can be effectively dissipated to the cooling liquid from the fin-shaped, cylindrical, or prismatic protuberance and the cooling liquid in the cooling flow path can be rectified or diffused in the width direction of the cooling flow path by the fin-shaped, cylindrical, or prismatic protuberance.

In this case, preferably, the fin-shaped protuberance of the lid is formed so as to extend along the cooling flow path. With such a configuration, it is possible to obtain a rectifying action in which the cooling liquid is guided along the cooling flow path by the fin-shaped protuberance, and an increase in pressure loss can be suppressed as compared with a case where a fin shape is provided in a direction intersecting the cooling flow path.

In the power conversion device configured such that the lid is provided with the protuberance, preferably, a plurality of the protuberances of the lid is formed, and the plurality of protuberances is formed so as to have a protrusion height of 80% to 100% with respect to a depth direction of the cooling flow path.

In the power conversion device configured such that the lid is provided with the protuberance, preferably, the protuberance of the lid is formed such that a gap from a wall surface of the cooling flow path is 0.5 to 2.0 mm.

Preferably, the power conversion device according to the first aspect further includes a boost converter disposed on an input side of the inverter, boosting the DC power input from the DC power supply, and supplying the power to the inverter, in which the inverter includes a first switching element module and a second switching element module converting the DC power into the AC power, the DC-DC converter includes a converter switching element, a transformer, a resonance reactor, and a smoothing reactor, the boost converter includes a boost switching element module and a boost reactor, and the cooling flow path is formed such that the cooling liquid flows such that a component highest in heat resistance-based priority among the first switching element module, the second switching element module, the converter switching element, the transformer, the resonance reactor, the smoothing reactor, the boost switching element module, and the boost reactor is cooled first. With such a configuration, a component that is low in heat resistance and should be cooled in a reliable manner can be cooled first, and thus it is possible to reliably suppress a rise in the temperature of the component with low heat resistance.

In this case, preferably, the first switching element module and the second switching element module are disposed on one of the front side and the back side of the base and are cooled by the cooling liquid flowing through one of the front side flow path and the back side flow path, and the converter switching element, the transformer, the resonance reactor, the smoothing reactor, the boost switching element module, and the boost reactor are disposed on the other of the front side and the back side of the base and are cooled by the cooling liquid flowing through the other of the front side flow path and the back side flow path. With such a configuration, the first switching element module and the second switching element module of the inverter can be disposed on one surface of the base, the converter switching element, the transformer, the resonance reactor, and the smoothing reactor of the DC-DC converter and the boost switching element module and the boost reactor of the boost converter can be disposed on the other surface of the base, and each of the components can be effectively cooled.

In the power conversion device configured such that the base includes the lid, preferably, the lid includes a boost reactor lid where a boost reactor is disposed and a DC-DC converter lid where the DC-DC converter is disposed, and the boost reactor lid and the DC-DC converter lid are integrally formed.

In the power conversion device configured such that the base includes the lid, preferably, the lid includes the boost reactor lid where the boost reactor is disposed and the DC-DC converter lid where the DC-DC converter is disposed, and the boost reactor lid and the DC-DC converter lid are provided on at least one of the front side flow path and the back side flow path and are fixed to a tunnel-shaped flow path forming member connecting the front side flow path and the front side flow path, or the back side flow path from the back side flow path.

In the power conversion device according to the first aspect, preferably, a pressure loss of a cooling liquid cooling the DC-DC converter is 15% of a pressure loss of the entire cooling flow path.

A power conversion device according to a second aspect of this invention is a power conversion device including a cooling body, in which the cooling body has a single-stroke cooling flow path formed therein, and at least a part of the cooling flow path forms a front side flow path cooling a front side of the cooling body and a back side flow path cooling a back side of the cooling body.

Preferably, the power conversion device according to the second aspect further includes: an inverter converting DC power input from a DC power supply into AC power and supplying the power to a load; and a boost converter disposed on an input side of the inverter, boosting the DC power input from the DC power supply, and supplying the power to the inverter, in which the cooling body includes an inverter cooling surface where the inverter is disposed and a boost converter cooling surface where the boost converter is disposed.

In this case, preferably, the cooling body is configured such that a pressure loss of a cooling liquid cooling the inverter cooling surface and the boost converter cooling surface is 85% of a pressure loss of the entire cooling body.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a power conversion device according to an embodiment.

FIG. 2 is a perspective view of the power conversion device according to the embodiment.

FIG. 3 is a side view of the power conversion device according to the embodiment.

FIG. 4 is an exploded perspective view in which the power conversion device according to the embodiment is viewed from above.

FIG. 5 is an exploded perspective view in which the power conversion device according to the embodiment is viewed from below.

FIG. 6 is a top view of a base of the power conversion device according to the embodiment.

FIG. 7 is a bottom view of the base of the power conversion device according to the embodiment.

FIG. 8 is a side sectional view of the base of the power conversion device according to the embodiment.

### DETAILED DESCRIPTION OF THE INVENTION

Hereinafter, an embodiment of the present invention will be described with reference to the drawings.

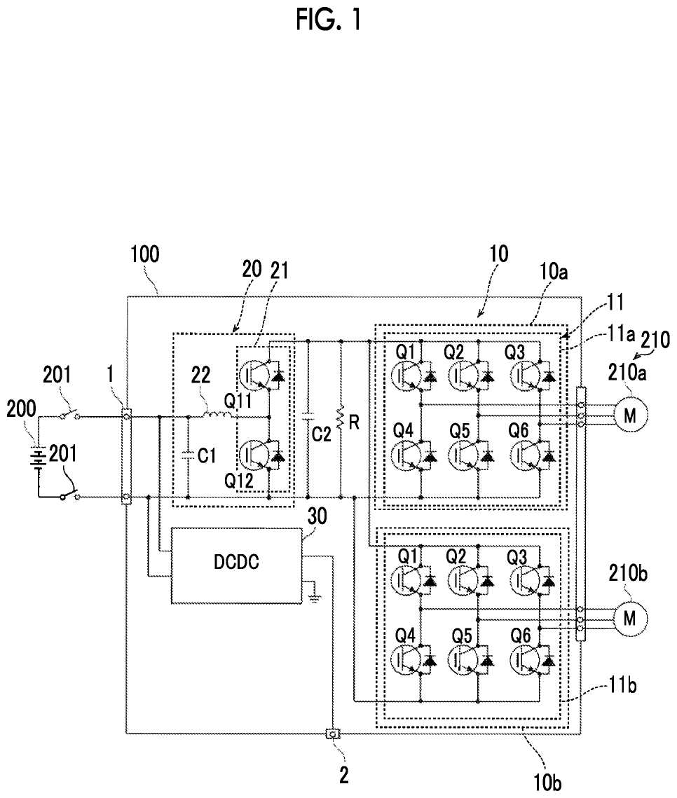

The configuration of a power conversion device 100 according to one embodiment of the present invention will be described with reference to FIGS. 1 to 8. The power conversion device 100 is mounted in, for example, a vehicle.

First, the circuit configuration of the power conversion device 100 will be described with reference to FIG. 1. The power conversion device 100 includes an inverter 10. The inverter 10 converts DC power input from a DC power supply 200 into AC power and supplies the power to a load 210. The load 210 is, for example, a motor. A switch 201 is provided between the power conversion device 100 and the DC power supply 200.

The inverter 10 includes a switching element module 11. The switching element module 11 converts DC power into AC power. In addition, the switching element module 11 includes semiconductor switching elements Q1, Q2, and Q3 constituting an upper arm and semiconductor switching elements Q4, Q5, and Q6 constituting a lower arm.

The inverter 10 includes a first inverter 10a and a second inverter 10b. The switching element module 11 includes a first switching element module 11a included in the first inverter 10a and a second switching element module 11b included in the second inverter 10b. In addition, the load 210 includes a first load 210a and a second load 210b. The first inverter 10a converts DC power input from the DC power supply 200 into AC power and supplies the power to the first load 210a. The second inverter 10b converts DC power input from the DC power supply 200 into AC power and supplies the power to the second load 210b.

The power conversion device 100 includes a boost converter 20. The boost converter 20 is disposed on the input side of the inverter 10. The boost converter 20 boosts DC power input from the DC power supply 200 and supplies the power to the inverter 10. The boost converter 20 includes a boost switching element module 21 and a reactor 22. The boost switching element module 21 includes boost switching elements Q11 and Q12. The boost switching elements Q11 and Q12 constitute an upper arm and a lower arm, respectively. In addition, the boost converter 20 includes a capacitor C1. The reactor 22 is provided between the positive side of the DC power supply 200 and the connection point between the boost switching element Q11 and the boost switching element Q12. The capacitor C1 is provided in parallel to the boost switching element Q12. The reactor 22 is an example of the “boost reactor” in the claims.

The power conversion device 100 includes a capacitor C2 and a resistor R. The capacitor C2 and the resistor R are provided between the boost converter 20 and the inverter 10. The capacitor C2 and the resistor R are provided in parallel to each other.

The power conversion device 100 includes a DC-DC converter 30. The DC-DC converter 30 converts the voltage of DC power into a different voltage. Specifically, the DC-DC converter 30 steps down the voltage of DC power input from the DC power supply 200 via a connector 1. In addition, the DC-DC converter 30 supplies the stepped-down voltage to an output terminal 2. The DC-DC converter 30 is an example of the “DC-DC converter” in the claims.

Next, the structure of the power conversion device 100 will be described.

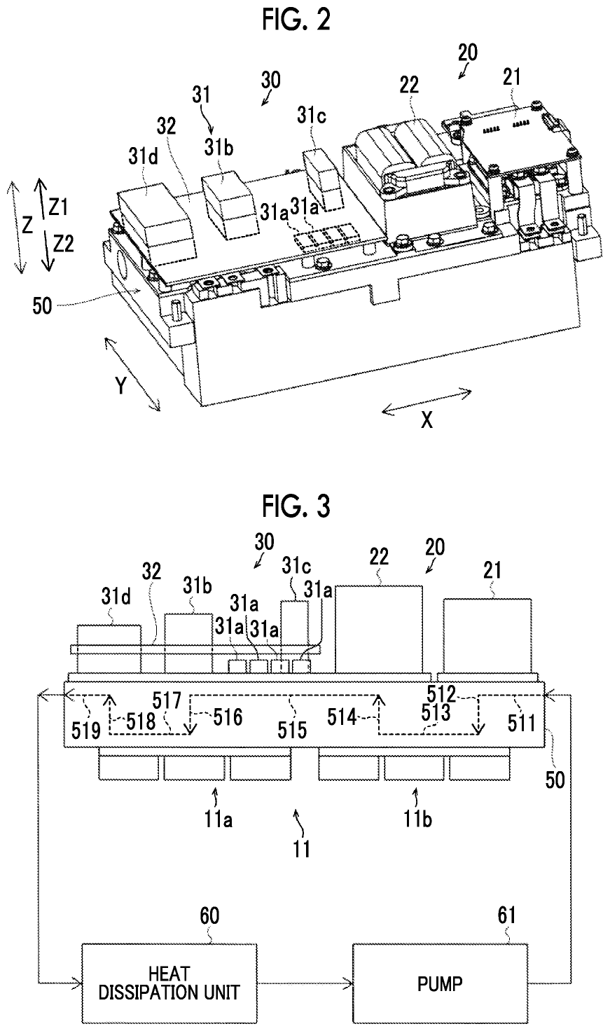

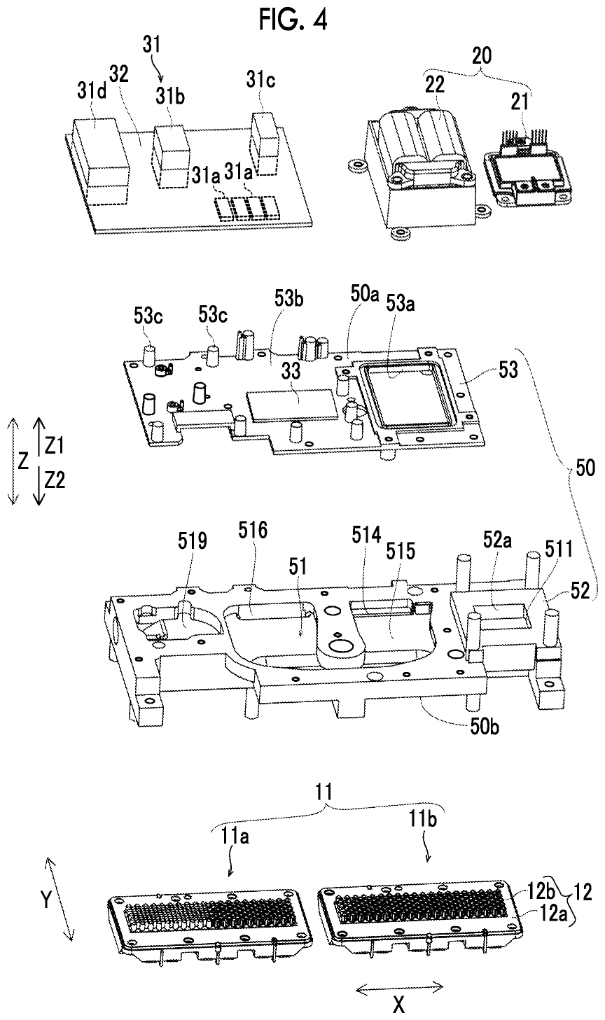

In the present embodiment, as illustrated in FIGS. 2 and 4, the DCDC converter 30 includes a DC-DC converter element 31 and a DC-DC converter substrate 32 on which the DC-DC converter element 31 is mounted. The DC-DC converter substrate 32 has a flat plate shape. The DC-DC converter element 31 mounted on the DC-DC converter substrate 32 includes a converter switching element 31a, a transformer 31b, a resonance reactor 31c, and a smoothing reactor 31d. The converter switching element 31a is provided on the back surface side (Z2 side) of the DC-DC converter substrate 32. The transformer 31b, the resonance reactor 31c, and the smoothing reactor 31d are provided so as to penetrate the DC-DC converter substrate 32.

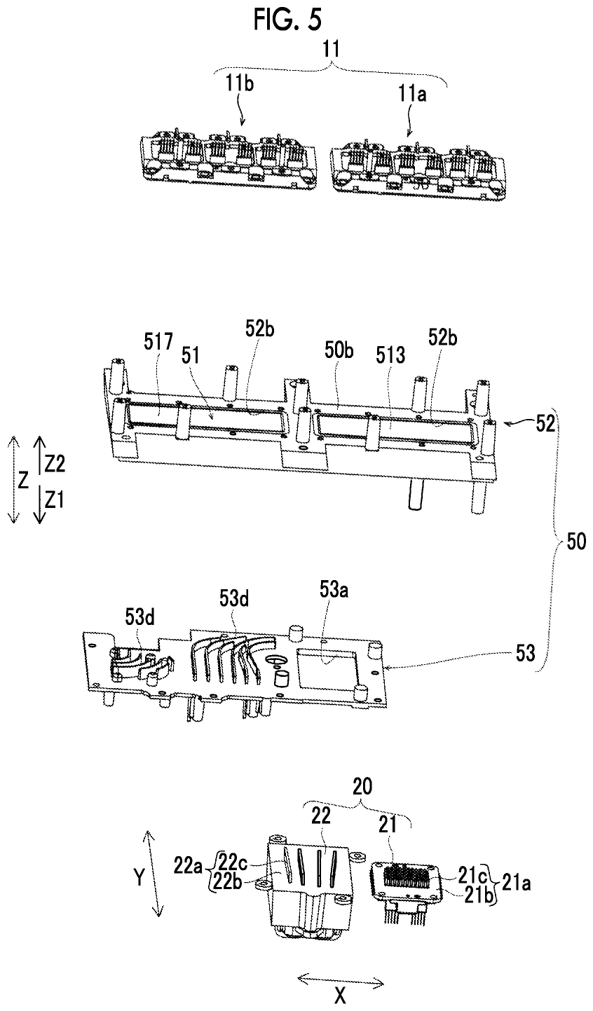

As illustrated in FIG. 5, the semiconductor switching elements Q1 to Q6 (see FIG. 1) are stored in the switching element module 11. The semiconductor switching elements Q1 to Q6 are covered with a housing made of resin or the like. As illustrated in FIG. 4, a lid 12 is disposed on a base 50 (described later) side (Z1 side) of the switching element module 11. The lid 12 is formed of a metal having a relatively high thermal conductivity such as aluminum. The lid 12 includes a flat plate-shaped main body 12a and a plurality of pillar portions 12b protruding toward the base 50. The pillar portion 12b is formed so as to protrude into a cooling flow path 51. The pillar portion 12b has, for example, a prismatic shape. The switching element module 11 has a rectangular shape when viewed from a direction perpendicular to the surface of the switching element module 11. The pillar portion 12b is an example of the “protuberance” in the claims.

As illustrated in FIGS. 2 to 5, the power conversion device 100 includes the base 50. The base 50 has a flat plate shape. The inverter 10 and the DCDC converter 30 are disposed on the base 50. In addition, the base 50 is formed of a metal having a relatively high thermal conductivity such as aluminum. The base 50 has a rectangular shape when viewed from a direction perpendicular to a surface 50a (front side surface (Z1 side surface)) and a back surface 50b (back side surface (Z2 side surface)) of the base 50.

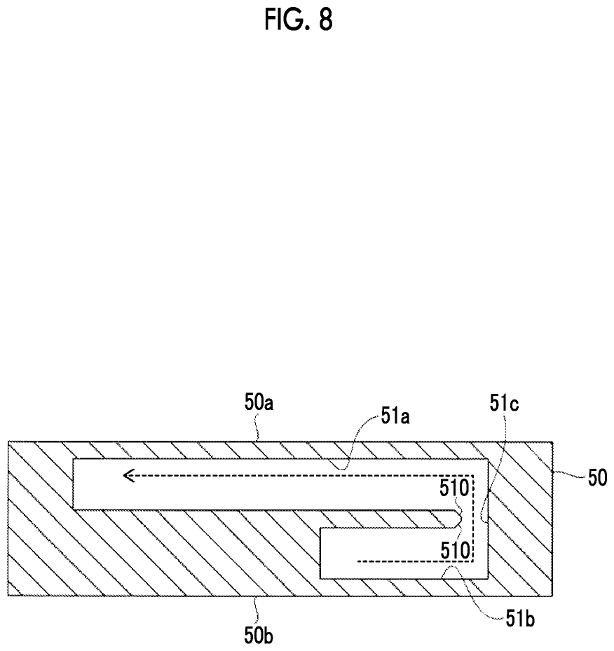

Here, in the present embodiment, as illustrated in FIG. 8, the base 50 includes the cooling flow path 51 through which a cooling liquid flows, and the cooling flow path 51 has a front side flow path 51a disposed on the front side and a back side flow path 51b connected to the front side flow path 51a and disposed on the back side.

In addition, the cooling flow path 51 has a connection flow path 51c connecting the front side flow path 51a and the back side flow path 51b in the base 50.

The switching element module 11 of the inverter 10 is attached to the base 50 along the surface 50a or the back surface 50b of the flat plate-shaped base 50. In addition, the DC-DC converter substrate 32 on which the DC-DC converter element 31 is mounted is attached to the base 50 along the surface 50a or the back surface 50b of the flat plate-shaped base 50.

Specifically, the switching element module 11 is attached to the base 50 along the back surface 50b of the flat plate-shaped base 50. In addition, the DC-DC converter substrate 32 on which the DC-DC converter element 31 is mounted is attached to the base 50 along the surface 50a of the flat plate-shaped base 50.

The first switching element module 11a and the second switching element module 11b are attached to the base 50 along the back surface 50b of the flat plate-shaped base 50. Specifically, the first switching element module 11a and the second switching element module 11b are disposed adjacent to each other along the long side direction (X direction) of the first switching element module 11a and the second switching element module 11b.

The boost converter 20 is attached to the base 50 along the surface 50a or the back surface 50b of the flat plate-shaped base 50. Specifically, the boost converter 20 is attached to the surface 50a of the base 50. In addition, the boost converter 20 is disposed adjacent to the DC-DC converter 30 along the longitudinal direction (X direction) of the flat plate-shaped base 50.

The boost converter 20 includes the boost switching element module 21 and the reactor 22. The boost switching element module 21 and the reactor 22 are attached to the base 50 along the surface 50a or the back surface 50b of the flat plate-shaped base 50. Specifically, the DC-DC converter substrate 32, the reactor 22, and the boost switching element module 21 are attached to the base 50 along the surface 50a of the flat plate-shaped base 50 and adjacent to each other. The DC-DC converter substrate 32, the reactor 22, and the boost switching element module 21 are attached to the surface 50a of the base 50 in this order.

As illustrated in FIG. 5, a lid 21a is disposed on the base 50 side (Z2 side) of the boost switching element module 21. The lid 21a is formed of a metal having a relatively high thermal conductivity such as aluminum. The lid 21a includes a flat plate-shaped main body 21b and a plurality of pillar portions 21c protruding toward the base 50. The pillar portion 21c is formed so as to protrude into the cooling flow path 51. The pillar portion 21c has, for example, a cylindrical shape. The boost switching element module 21 has a square shape when viewed from a direction perpendicular to the surface of the boost switching element module 21. The pillar portion 21c is an example of the “protuberance” in the claims.

A lid 22a is disposed on the base 50 side (Z2 side) of the reactor 22. The lid 22a is formed of a metal having a relatively high thermal conductivity such as aluminum. The lid 22a includes a main body 22b and a plurality of fins 22c protruding toward the base 50. The fin 22c is formed so as to protrude into the cooling flow path 51. The fin 22c is formed so as to extend along the cooling flow path 51. The fin 22c is an example of the “protuberance” in the claims.

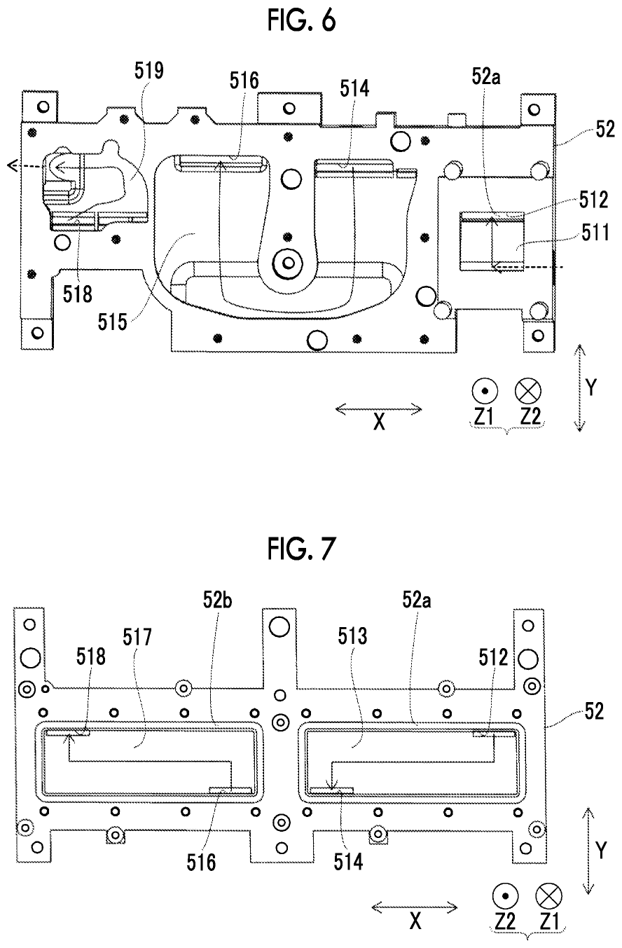

As illustrated in FIGS. 4 and 5, the base 50 includes a metallic cooling main body 52 where the cooling flow path 51 is formed and the lids 12, 21a, and 22a and a lid 53, which are metallic and form the cooling flow path 51 together with the cooling main body 52. In addition, the inverter 10 and the DC-DC converter 30 are attached to the lids 12 and 53 disposed on the front side and the back side of the base 50. Specifically, the DC-DC converter substrate 32 is attached to the lid 53. Specifically, the cooling flow path 51 is provided on both the surface 50a and the back surface 50b of the base 50 (see FIGS. 6 and 7). The lid 53 covers the cooling flow path 51 provided on the surface 50a of the base 50. The lid 53 has a rectangular shape and a flat plate shape. The DC-DC converter substrate 32 is disposed along a surface 53b of the lid 53. The DC-DC converter substrate 32 is attached to a pillar portion 53c provided on the lid 53 by, for example, a screw. The lid 53 is attached to the cooling main body 52 by, for example, a screw. As a result, the DC-DC converter substrate 32 and the DC-DC converter element 31 can be easily replaced simply by screw removal.

The lid 53 is formed of a metal having a relatively high thermal conductivity such as aluminum. The lid 53 is provided with a fin 53d protruding into the cooling flow path 51. The fin 53d is formed so as to extend along the cooling flow path 51. The fin 53d is an example of the “protuberance” in the claims.

In addition, the lid 12 covers the cooling flow path 51 provided on the back surface 50b of the base 50. Two lids 12 are provided. The lid 12 has a rectangular shape and a flat plate shape. The first switching element module 11a and the second switching element module 11b are attached to the lids 12, respectively.

In addition, the lid 21a covers the cooling flow path 51 provided on the surface 50a of the base 50. The lid 21a has a rectangular shape and a flat plate shape. The boost switching element module 21 is attached to the lid 21a.

As illustrated in FIG. 4, the DC-DC converter element 31 includes the converter switching element 31a. The converter switching element 31a is attached so as to come into contact with the lid 53 via a heat conductive member 33 on the lid 53 side surface (Z2 side surface) of the DC-DC converter substrate 32. In other words, the lid 53, the heat conductive member 33, and the converter switching element 31a are stacked in this order. Heat generated from the converter switching element 31a is dissipated to the lid 53 via the heat conductive member 33. The heat conductive member 33 is made of, for example, a ceramic sheet.

In addition, the lid 53 is provided with a hole portion 53a. The reactor 22 is disposed so as to cover the hole portion 53a of the lid 53. In other words, the reactor 22 is disposed so as to cover the cooling flow path 51. Heat generated from the reactor 22 is dissipated to the cooling liquid flowing through the cooling flow path 51. The reactor 22 is attached to the lid 53 by, for example, a screw.

The cooling main body 52 is provided with a hole portion 52a. The boost switching element module 21 is disposed so as to cover the hole portion 52a of the cooling main body 52. In other words, the boost switching element module 21 is disposed so as to cover the cooling flow path 51. Heat generated from the boost switching element module 21 is dissipated to the cooling liquid flowing through the cooling flow path 51. The boost switching element module 21 is attached to the cooling main body 52 by, for example, a screw.

As illustrated in FIG. 5, the cooling main body 52 is provided with a pair of hole portions 52b. The first switching element module 11a and the second switching element module 11b are disposed so as to cover the hole portions 52b, respectively. In other words, the first switching element module 11a and the second switching element module 11b are disposed so as to cover the cooling flow path 51. Heat generated from the switching element module 11 is dissipated to the cooling liquid flowing through the cooling flow path 51.

In the present embodiment, as illustrated in FIG. 3, the cooling flow path 51 is formed such that the front side flow path 51a and the back side flow path 51b are alternately connected and a cooling liquid alternately passes through the front side surface and the back side surface of the base 50. Specifically, the cooling flow path 51 includes cooling flow paths 511, 515, and 519 as the front side flow path 51a disposed on the front side (surface 50a side), cooling flow paths 513 and 517 as the back side flow path 51b disposed on the back side (back surface 50b side), and cooling flow paths 512, 514, 516, and 518 as the connection flow path 51c. The cooling flow path 51 is formed such that a cooling fluid flows in from one end side in the longitudinal direction (X direction) of the base 50 and the cooling fluid flows out to the other end side.

As for the cooling flow path 51, the cooling flow paths 511, 512, 513, 514, 515, 516, 517, 518, and 519 are connected from upstream toward downstream in this order. In other words, as illustrated in FIGS. 3, 6, and 7, as for the cooling flow path 51, a cooling liquid flows in from the cooling flow path 511 of the front side flow path 51a and the cooling liquid flows out through the cooling flow path 512 of the connection flow path 51c, the cooling flow path 513 of the back side flow path 51b, the cooling flow path 514 of the connection flow path 51c, the cooling flow path 515 of the front side flow path 51a, the cooling flow path 516 of the connection flow path 51c, the cooling flow path 517 of the back side flow path 51b, the cooling flow path 518 of the connection flow path 51c, and the cooling flow path 519 of the front side flow path 51a.

In addition, the cooling liquid flowing out of the cooling flow path 51 is heat-dissipated by a heat dissipation unit 60 and cooled. In addition, the cooling liquid cooled by the heat dissipation unit 60 is sent by a pump 61 and flows into the cooling flow path 51 again. The heat dissipation unit 60 includes a heat exchanger and is cooled by external air. The heat dissipation unit 60 is, for example, a radiator. The pump 61 may be disposed between the outlet of the cooling flow path 51 and the heat dissipation unit 60 and the cooling liquid that is yet to be heat-dissipated by the heat dissipation unit 60 may be sent by the pump 61. In addition, the cooling liquid is, for example, a liquid such as water and antifreeze.

In addition, in the present embodiment, as illustrated in FIG. 3, the inverter 10 is disposed on the back side of the base 50 and is cooled by the cooling liquid flowing through the back side flow path 51b. Specifically, the first switching element module 11a and the second switching element module lib are disposed on the back side of the base 50 and are cooled by the cooling liquid flowing through the back side flow path 51b.

In addition, in the present embodiment, the DC-DC converter 30 is disposed on the front side of the base 50 and is cooled by the cooling liquid flowing through the front side flow path 51a. Specifically, the converter switching element 31a, the transformer 31b, the resonance reactor 31c, the smoothing reactor 31d, the boost switching element module 21, and the reactor 22 are disposed on the front side of the base 50 and are cooled by the cooling liquid flowing through the front side flow path 51a.

In addition, in the present embodiment, as illustrated in FIG. 8, the connection flow path 51c has a chamfered corner. Specifically, chamfered portions 510 are provided at the parts of the connection flow path 51c connected to the front side flow path 51a and the back side flow path 51b.

In addition, in the present embodiment, the cooling flow path 51 is formed such that a cooling liquid flows such that the component highest in heat resistance-based priority among the first switching element module 11a, the second switching element module 11b, the converter switching element 31a, the transformer 31b, the resonance reactor 31c, the smoothing reactor 31d, the boost switching element module 21, and the reactor 22 is cooled first. Specifically, as for the cooling flow path 51, a flow path is formed such that the boost switching element module 21 and the reactor 22, which are relatively low in heat resistance, are cooled on the upstream side.

In addition, the cooling flow path 51 is formed such that a cooling liquid flows such that cooling is performed in the order of the boost switching element module 21, the second switching element module 11b, the reactor 22, the resonance reactor 31c, the converter switching element 31a, the transformer 31b, the first switching element module 11a, and the smoothing reactor 31d.

As illustrated in FIGS. 3, 6, and 7, the boost switching element module 21 is cooled by the cooling liquid flowing through the cooling flow path 511. In addition, the second switching element module 11b is cooled by the cooling liquid flowing through the cooling flow path 513. In addition, the resonance reactor 31c, the converter switching element 31a, and the transformer 31b are cooled by the cooling liquid flowing through the cooling flow path 515. In addition, the first switching element module 11a is cooled by the cooling liquid flowing through the cooling flow path 517. In addition, the smoothing reactor 31d is cooled by the cooling liquid flowing through the cooling flow path 519.

### Effects of Present Embodiment

The following effects can be obtained in the present embodiment.

In the present embodiment, as described above, the inverter 10 and the DC-DC converter 30 are disposed on the front side and the back side of the flat plate-shaped base 50, and the base 50 is provided with the cooling flow path 51 having the front side flow path 51a disposed on the front side and the back side flow path 51b connected to the front side flow path 51a and disposed on the back side. As a result, a cooling liquid is capable of sequentially flowing through the front side flow path 51a and the back side flow path 51b, and thus the inverter 10 and the DCDC converter 30 disposed on the front side and the back side of the base 50 can be sequentially cooled. As a result, it is possible to suppress the occurrence of a temperature difference between cooling liquids flowing at the same position, and thus it is possible to suppress the generation of unintended convection of a cooling liquid attributable to a temperature difference. As a result, the inverter 10 and the DC-DC converter 30 can be efficiently cooled by the cooling liquid flowing through the cooling flow path 51. In addition, as compared with the case of a configuration in which the inverter 10 and the DC-DC converter 30 are disposed in separate bases and cooled by cooling flow paths respectively provided in the bases, the configuration of the power conversion device 100 including the inverter 10 and the DCDC converter 30 can be made compact.

In addition, in the present embodiment, as described above, the cooling flow path 51 has the connection flow path 51c that connects the front side flow path 51a and the back side flow path 51b in the base 50. As a result, the cooling flow path 51 can be formed such that a cooling liquid sequentially flows through the front side flow path 51a and the back side flow path 51b in the base 50, and thus the configuration of the base 50 can be simplified unlike in a case where the front side flow path 51a and the back side flow path 51b are connected outside the base 50.

In addition, in the present embodiment, as described above, the cooling flow path 51 is formed such that the front side flow path 51a and the back side flow path 51b are alternately connected and a cooling liquid alternately passes through the front side surface and the back side surface of the base 50. As a result, a cooling liquid is capable of alternately and sequentially flowing through the front side flow path 51a and the back side flow path 51b, and thus the inverter 10 and the DC-DC converter 30 disposed on the front side and the back side of the base 50 can be alternately and sequentially cooled.

In addition, in the present embodiment, as described above, the inverter 10 is disposed on the back side of the base 50 and is cooled by the cooling liquid flowing through the back side flow path 51b, and the DC-DC converter 30 is disposed on the front side of the base 50 and is cooled by the cooling liquid flowing through the front side flow path 51a. As a result, the components and elements included in the inverter 10 can be disposed on the back side surface of the base 50, and the components and elements included in the DC-DC converter 30 can be disposed on the front side surface of the base 50. Accordingly, it is possible to suppress an increase in the wiring connecting the front side and the back side of the base 50. As a result, it is possible to suppress the wiring structure of the power conversion device 100 becoming complex.

In addition, in the present embodiment, as described above, the base 50 includes the metallic cooling main body 52 where the cooling flow path 51 is formed and the lids 12, 21a, 22a, and 53, which are metallic and form the cooling flow path 51 together with the cooling main body 52. In addition, the inverter 10 and the DC-DC converter 30 are attached to the lids 12 and 53 disposed on the front side and the back side of the base 50. As a result, the lids 12 and 53 to which the inverter 10 and the DC-DC converter 30 are attached can be brought into direct contact with the cooling liquid flowing through the cooling flow path 51, and thus heat can be efficiently removed from the inverter 10 and the DCDC converter 30 via the lids 12 and 53.

In addition, in the present embodiment, as described above, the lids 12, 21a, 22a, and 53 are provided with protuberances (pillar portions 12b and 21c and fins 22c and 53d) protruding into the cooling flow path 51. As a result, the area of contact of the lids 12, 21a, 22a, and 53 with a cooling liquid can be increased by the protuberances (pillar portions 12b and 21c and fins 22c and 53d), and thus heat from the inverter 10 and the DC-DC converter 30 can be more efficiently transferred to a cooling liquid via the lids 12, 21a, 22a, and 53.

In addition, in the present embodiment, as described above, the protuberances (pillar portions 12b and 21c and fins 22c and 53d) of the lids 12, 21a, 22a, and 53 are formed in a fin shape, a cylindrical shape, or a prismatic shape. As a result, heat can be effectively dissipated to a cooling liquid from the fin-shaped, cylindrical, or prismatic protuberances (pillar portions 12b and 21c and fins 22c and 53d) and the cooling liquid in the cooling flow path 51 can be rectified or diffused in the width direction of the cooling flow path 51 by the fin-shaped, cylindrical, or prismatic protuberances (pillar portions 12b and 21c and fins 22c and 53d).

In addition, in the present embodiment, as described above, the fins 22c and 53d of the lids 22a and 53 are formed so as to extend along the cooling flow path 51. As a result, it is possible to obtain a rectifying action in which a cooling liquid is guided along the cooling flow path 51 by the fins 22c and 53d, and an increase in pressure loss can be suppressed as compared with a case where a fin shape is provided in a direction intersecting the cooling flow path 51.

In addition, in the present embodiment, as described above, the connection flow path 51c has a chamfered corner. As a result, an increase in pressure loss in the corner of the connection flow path 51c can be suppressed as compared with a case where the connection flow path 51c has no chamfered corner.

In addition, in the present embodiment, as described above, the boost converter 20 is disposed on the input side of the inverter 10, boosts DC power input from the DC power supply, and supplies the power to the inverter 10. In addition, the inverter 10 includes the first switching element module 11a and the second switching element module 11b converting DC power into AC power. In addition, the DC-DC converter 30 includes the converter switching element 31a, the transformer 31b, the resonance reactor 31c, and the smoothing reactor 31d. In addition, the boost converter 20 includes the boost switching element module 21 and the reactor 22. The cooling flow path 51 is formed such that a cooling liquid flows such that the component highest in heat resistance-based priority among the first switching element module 11a, the second switching element module 11b, the converter switching element 31a, the transformer 31b, the resonance reactor 31c, the smoothing reactor 31d, the boost switching element module 21, and the reactor 22 is cooled first. As a result, a component that is low in heat resistance and should be cooled in a reliable manner can be cooled first, and thus it is possible to reliably suppress a rise in the temperature of a component with low heat resistance.

In addition, in the present embodiment, as described above, the first switching element module 11a and the second switching element module 11b are disposed on the back side of the base 50 and are cooled by the cooling liquid flowing through the back side flow path 51b, and the converter switching element 31a, the transformer 31b, the resonance reactor 31c, the smoothing reactor 31d, the boost switching element module 21, and the reactor 22 are disposed on the front side of the base 50 and are cooled by the cooling liquid flowing through the front side flow path 51a. As a result, the first switching element module 11a and the second switching element module 11b of the inverter 10 can be disposed on the back side surface of the base 50, the converter switching element 31a, the transformer 31b, the resonance reactor 31c, and the smoothing reactor 31d of the DC-DC converter 30 and the boost switching element module 21 and the reactor 22 of the boost converter 20 can be disposed on the front side surface of the base 50, and each of the components can be effectively cooled.

### Modification Examples

The embodiment disclosed above should be considered to be exemplary and unrestrictive in every respect. The scope of the present invention is shown by the claims rather than the description of the embodiment and further includes every change (modification example) within the meaning and scope equivalent to the claims.

In the example shown in the above embodiment, the switching element module 11 is attached to the back surface 50b of the base 50 and the DC-DC converter substrate 32 is attached to the surface 50a of the base 50. However, the present invention is not limited thereto. For example, the switching element module 11 may be attached to the surface 50a of the base 50 and the DC-DC converter substrate 32 may be attached to the back surface 50b of the base 50. In addition, both the switching element module 11 and the DC-DC converter substrate 32 may be attached to the surface 50a of the base 50. In addition, both the switching element module 11 and the DC-DC converter substrate 32 may be attached to the back surface 50b of the base 50.

In the example shown in the above embodiment, both the first switching element module 11a and the second switching element module 11b are attached to the back surface 50b of the base 50. However, the present invention is not limited thereto. For example, the first switching element module 11a and the second switching element module 11b may be attached to different surfaces of the base 50.

In the example shown in the above embodiment, the boost converter 20 is attached to the surface 50a of the base 50. However, the present invention is not limited thereto. For example, the boost converter 20 may be attached to the back surface 50b of the base 50.

In the example shown in the above embodiment, both the boost switching element module 21 and the reactor 22 are attached to the surface 50a of the base 50. However, the present invention is not limited thereto. For example, both the boost switching element module 21 and the reactor 22 may be attached to the back surface 50b of the base 50. In addition, the boost switching element module 21 and the reactor 22 may be attached to different surfaces of the base 50.

In the example shown in the above embodiment, the base 50 is separated into the cooling main body 52 and the lid 53. However, the present invention is not limited thereto. For example, the base 50 may be integrally formed without separating the cooling main body 52 and the lid 53.

In the example shown in the above embodiment, the DC-DC converter element 31 mounted on the DC-DC converter substrate 32 includes the converter switching element 31a, the transformer 31b, the resonance reactor 31c, and the smoothing reactor 31d. However, the present invention is not limited thereto. For example, the DC-DC converter element 31 mounted on the DC-DC converter substrate 32 may include an element other than these elements.

In the example shown in the above embodiment, the cooling flow path 51 is formed such that a cooling liquid flows such that cooling is performed in the order of the boost switching element module 21, the second switching element module 11b, the reactor 22, the resonance reactor 31c, the converter switching element 31a, the transformer 31b, the first switching element module 11a, and the smoothing reactor 31d. However, the present invention is not limited thereto. For example, the cooling flow path 51 may be formed such that a cooling liquid flows such that the plurality of components is cooled in an order other than the above.

In the above embodiment, in other words in detail, a plurality of protuberances of the lids 12, 21a, and 53 is formed and the plurality of protuberances in the power conversion device is formed so as to have a protrusion height of 80% to 100% with respect to the depth direction of the flow path 51 formed in the base 50 (cooling body). Preferably, the plurality of protuberances is formed so as to have a protrusion height of 80% to 93% with respect to the depth direction of the cooling flow path. Specifically, the gap between the protuberance and the flow path is formed to be 0.0 mm to 1.5 mm. The flow path depth is the vertically measured length from the lid flow path side surface to the flow path bottom surface. With such a configuration, heat dissipation improvement can be expected.

In the above embodiment, in other words in detail, the protuberances of the lids 12, 21a, and 53 in the power conversion device are formed such that the gap from the flow path wall surface is 0.5 mm to 2.0 mm. With such a configuration, heat dissipation improvement can be expected.

In the above embodiment, in other words, the base 50 (cooling body) may have a single-stroke flow path. At least a part of the flow path may form a front side flow path cooling the front side of the cooling body and a back side flow path cooling the back side of the cooling body. With such a configuration, it is not necessary to provide a design for uniform flow division, such as a flow division plate, as compared with a flow path in which a flow is divided in parallel on the front and back sides. Accordingly, power conversion device cost reduction can be expected.

In addition, desirably, in the flow path formed in the base 50, the pressure loss of the cooling liquid cooling the DC-DC converter is 15% of the pressure loss of the entire flow path formed in the base 50. With such a configuration, the heat dissipation of a component that has priority over the DC-DC converter can be expected to be improved.

To put the above embodiment in another way, the power conversion device further includes an inverter converting DC power input from a DC power supply into AC power and supplying the power to a load, a DC-DC converter converting a voltage of the DC power into a different voltage, and a boost converter disposed on an input side of the inverter, boosting the DC power input from the DC power supply, and supplying the power to the inverter, in which a cooling body includes an inverter cooling surface where the inverter is disposed, a converter cooling surface where the DC-DC converter is cooled, and a boost converter cooling surface where the boost converter is disposed. With such a configuration, power conversion device size reduction can be expected.

To put the above embodiment in another way, in the power conversion device, the cooling body is configured such that the pressure losses of the cooling liquids cooling the inverter cooling surface and the boost converter and converter cooling surfaces are 85% and 15% of the pressure loss of the entire cooling body, respectively. With such a configuration, the inverter and the boost converter can be expected to be improved in heat dissipation in preference to the DC-DC converter.

To put the above embodiment in another way, in the power conversion device, the connection flow path includes a partition plate adjusting a flow of a cooling liquid flowing into at least one of the front side flow path and the back side flow path. Specifically, in this configuration, the connection flow path is provided with a rib and the cooling liquid can be thoroughly supplied to the front side flow path or the back side flow path of inflow. As illustrated in FIG. 6, the flow path 514 is provided with a rib so as to have an opening ratio of 3 to 4:1 from the left. The flow path 518 is provided with a rib so as to have an opening ratio of 2.4 to 2.7:1.5 to 1.8:1 from the left.

To put the above embodiment in another way, in the power conversion device, the cooling flow path includes a groove inclined to the connection flow path. Specifically, a groove (not illustrated) inclined with respect to the flow path 514 in FIG. 7 is provided in the bottom portion of the flow path 513. Desirably, the groove is provided near the flow path wall surface.

To put the above embodiment in another way, in the power conversion device, the lid includes a boost reactor lid where a boost reactor is disposed and a DC-DC converter lid where a DC-DC converter is disposed, and the boost reactor lid and the DC-DC converter lid are integrally formed. As illustrated in FIG. 5, the lid 53 is formed such that the reactor 22 and the DCDC converter are disposed.

To put the above embodiment in another way, in the power conversion device, the lid includes a boost reactor lid where a boost reactor is disposed and a DC-DC converter lid where a DC-DC converter is disposed, and the boost reactor lid and the DC-DC converter lid are provided on at least one of the front side flow path and the back side flow path and are fixed to a tunnel-shaped flow path forming member connecting the front side flow path and the front side flow path, or the back side flow path from the back side flow path. More specifically, in a case where the boost reactor lid and the DC-DC converter lid are separately formed, the periphery of each lid needs to be fixed and sealed to the cooling body main body. In a case where the lid 53 is separated into a boost reactor lid and a DC-DC converter lid as in FIG. 4, the cooling flow path 515 straddles the boost reactor lid and the DC-DC converter lid, and thus sealing cannot be performed. Accordingly, a tunnel-shaped flow path forming member is provided in the cooling flow path 515.

Although a power conversion device including a DC-DC converter has been described in the above embodiments, the same effect can be obtained even in a state where no DC-DC converter is mounted on the base 50.

What is claimed is:

1. A power conversion device comprising:
an inverter converting DC power input from a DC power supply into AC power and supplying the power to a load;
a DC-DC converter converting a voltage of the DC power into a different voltage; and
a flat plate-shaped base where the inverter and the DC-DC converter are disposed on a front side and a back side,
wherein the base includes a cooling flow path having a front side flow path disposed on the front side and a back side flow path connected to the front side flow path and disposed on the back side.

2. The power conversion device according to claim 1,
wherein the cooling flow path further has a connection flow path connecting the front side flow path and the back side flow path in the base.

3. The power conversion device according to claim 1,
wherein the cooling flow path is formed such that the front side flow path and the back side flow path are alternately connected and a cooling liquid alternately passes through a front side surface and a back side surface of the base.

4. The power conversion device according to claim 2, wherein the connection flow path has a chamfered corner.

5. The power conversion device according to claim 2,
wherein the connection flow path includes a partition plate adjusting a flow of a cooling liquid flowing into at least one of the front side flow path and the back side flow path.

6. The power conversion device according to claim 2,
wherein the cooling flow path includes a groove inclined to the connection flow path.

7. The power conversion device according to claim 1,
wherein the inverter is disposed on one of the front side and the back side of the base and is cooled by a cooling liquid flowing through one of the front side flow path and the back side flow path, and
the DC-DC converter is disposed on the other of the front side and the back side of the base and is cooled by a cooling liquid flowing through the other of the front side flow path and the back side flow path.

8. The power conversion device according to claim 1,
wherein the base includes a metallic cooling main body where the cooling flow path is formed and a metallic lid forming the cooling flow path together with the cooling main body, and
at least one of the inverter and the DC-DC converter is attached to the lid disposed on the front side and the back side of the base.

9. The power conversion device according to claim 8,
wherein the lid is provided with a protuberance protruding into the cooling flow path.

10. The power conversion device according to claim 9,
wherein the protuberance of the lid is formed in a fin shape, a cylindrical shape, or a prismatic shape.

11. The power conversion device according to claim 10,
wherein the fin-shaped protuberance of the lid is formed so as to extend along the cooling flow path.

12. The power conversion device according to claim 9,
wherein a plurality of the protuberances of the lid is formed, and the plurality of protuberances is formed so as to have a protrusion height of 80% to 100% with respect to a depth direction of the cooling flow path.

13. The power conversion device according to claim 9,
wherein the protuberance of the lid is formed such that a gap from a wall surface of the cooling flow path is 0.5 to 2.0 mm.

14. The power conversion device according to claim 1, further comprising a boost converter disposed on an input side of the inverter, boosting the DC power input from the DC power supply, and supplying DC power to the inverter,
wherein the inverter includes a first switching element module and a second switching element module converting the DC power into the AC power,
the DC-DC converter includes a converter switching element, a transformer, a resonance reactor, and a smoothing reactor, the boost converter includes a boost switching element module and a boost reactor, and
the cooling flow path is formed such that a cooling liquid flows such that a component highest in heat resistance-based priority among the first switching element module, the second switching element module, the converter switching element, the transformer, the resonance reactor, the smoothing reactor, the boost switching element module, and the boost reactor is cooled first.

15. The power conversion device according to claim 14,
wherein the first switching element module and the second switching element module are disposed on one of the front side and the back side of the base and are cooled by a cooling liquid flowing through one of the front side flow path and the back side flow path, and
the converter switching element, the transformer, the resonance reactor, the smoothing reactor, the boost switching element module, and the boost reactor are disposed on the other of the front side and the back side of the base and are cooled by a cooling liquid flowing through the other of the front side flow path and the back side flow path.

16. The power conversion device according to claim 8,
wherein the lid includes a boost reactor lid where a boost reactor is disposed and a DC-DC converter lid where the DC-DC converter is disposed, and
the boost reactor lid and the DC-DC converter lid are integrally configured.

17. The power conversion device according to claim 8,
wherein the lid includes a boost reactor lid where a boost reactor is disposed and a DC-DC converter lid where the DC-DC converter is disposed, and
the boost reactor lid and the DC-DC converter lid are provided on at least one of the front side flow path and the back side flow path and are fixed to a tunnel-shaped flow path forming member connecting the front side flow path and the front side flow path, or the back side flow path from the back side flow path.

18. The power conversion device according to claim 1,
wherein a pressure loss of a cooling liquid cooling the DC-DC converter is 15% of a pressure loss of the entire cooling flow path.

19. A power conversion device comprising a cooling body,
wherein the cooling body has a single-stroke cooling flow path formed therein, and
at least a part of the cooling flow path forms a front side flow path cooling a front side of the cooling body and a back side flow path cooling a back side of the cooling body.

20. The power conversion device according to claim 19, further comprising:
an inverter converting DC power input from a DC power supply into AC power and supplying the AC power to a load; and
a boost converter disposed on an input side of the inverter, boosting the DC power input from the DC power supply, and supplying the DC power to the inverter,
wherein the cooling body includes an inverter cooling surface where the inverter is disposed and a boost converter cooling surface where the boost converter is disposed.

21. The power conversion device according to claim 20,
wherein the cooling body is configured such that a pressure loss of a cooling liquid cooling the inverter cooling surface and the boost converter cooling surface is 85% of a pressure loss of the entire cooling body.
